(19) United States
(12) Patent Application Publication
(10) Pub. No.: US 2025/0385152 A1
(43) Pub. Date: Dec. 18, 2025

(54) SEMICONDUCTOR DEVICE INCLUDING AN INTEGRATED WAFER LEVEL HEAT SINK WINDOW PLATE

(71) Applicant: Sandisk Technologies, Inc., Milpitas, CA (US)

(72) Inventors: Yuanheng Zhang, Shanghai (CN); Derek Mong, Penang (MY); Shrikar Bhagath, San Jose, CA (US); Fen Yu, Shanghai (CN); Paul Qu, Shanghai (CN); Shaopeng Dong, Shanghai (CN); Rui Guo, Shanghai (CN); Jiun Dong Loeh, Penang (MY); Jerry Tang, Shanghai (CN); Zengyu Zhou, Shanghai (CN)

(73) Assignee: Sandisk Technologies, Inc., Milpitas, CA (US)

(21) Appl. No.: 18/740,674

(22) Filed: Jun. 12, 2024

(51) Int. Cl. H01L 23/367; H01L 23/373; H01L 23/498; H01L 25/065

(52) U.S. Cl. CPC H01L 23/3672; H01L 23/3736; H01L 23/49816; H01L 25/0657; H01L 2225/06506; H01L 2225/06589

(57) ABSTRACT

A semiconductor device includes a semiconductor controller die and a stack of one or more semiconductor memory dies. In one example, the controller die may have an integrated heat sink window plate, or HSWP, formed on top of the die. In other examples, an uppermost memory die in the stack of memory dies may include an integrated HSWP. The HSWP may be formed on the controller die and/or the memory die at the wafer level.

### BACKGROUND

The strong growth in demand for portable consumer electronics is driving the need for high-capacity storage devices. Non-volatile semiconductor memory devices are widely used to meet the ever-growing demands on digital information storage and exchange. Their portability, versatility and rugged design, along with their high reliability and large capacity, have made such memory devices ideal for use in a wide variety of electronic products, including for example digital cameras, digital music players, video game consoles, computers, cellular telephones and SSD (solid state drives).

While many varied packaging configurations are known, flash memory semiconductor packages may in general be assembled as system-in-a-package (SIP), where a controller die and a number of memory dies are mounted and interconnected to an upper surface of a substrate such as a printed circuit board. The package may then be encased in a mold compound.

Current controller dies generate heat which needs to be conducted away from the dies. Moreover, there are next generation graphics processing units and AI processing units which operate at high speeds and generate a significant amount of heat. It is known to mount a heat sink on top of the mold compound to draw heat away from the controller. However, such heat conduction schemes add height to the overall controller, and are also not very effective at removing heat from the controller.

### DESCRIPTION OF THE DRAWINGS

FIG. 1 is a flowchart of the overall wafer-level fabrication of an HSWP controller die and an HSWP memory die according to embodiments of the present technology.

FIG. 2 is a perspective view of integrated circuit wafer according to embodiments of the present technology.

FIG. 3 is a sectional view where the integrated circuit wafer includes semiconductor controller dies according to embodiments of the present technology.

FIG. 4 is a sectional view where the integrated circuit wafer includes semiconductor memory dies according to embodiments of the present technology.

FIG. 5 is a perspective view of an HSWP wafer at a first fabrication stage according to embodiments of the present technology.

FIG. 6 is a sectional view of an HSWP wafer at a first fabrication stage according to embodiments of the present technology.

FIG. 7 is a perspective view of an HSWP wafer at a second fabrication stage according to embodiments of the present technology.

FIG. 8 is a sectional view of an HSWP wafer at a second fabrication stage according to embodiments of the present technology.

FIG. 9 is an enlarged sectional view of an HSWP wafer at a second fabrication stage according to embodiments of the present technology.

FIG. 10 is a perspective view of an HSWP wafer at a third fabrication stage according to embodiments of the present technology.

FIG. 11 is a sectional view of an HSWP wafer at a third fabrication stage according to embodiments of the present technology.

FIG. 12 is a perspective view of an HSWP wafer at a fourth fabrication stage according to embodiments of the present technology.

FIG. 13 is a sectional view of an HSWP wafer at a fourth fabrication stage according to embodiments of the present technology.

FIG. 14 is a perspective view of an HSWP wafer using an alternative fabrication method according to embodiments of the present technology.

FIG. 15 is a sectional view of an HSWP wafer using an alternative fabrication method according to embodiments of the present technology.

FIG. 16 is an exploded perspective view of an integrated circuit wafer positioned for mounting on an HSWP wafer according to embodiments of the present technology.

FIG. 17 is a sectional view of the integrated circuit wafer of FIG. 16.

FIG. 18 is a sectional view of the HSWP wafer of FIG. 16.

FIG. 19 is a sectional view of a dicing tape of FIG. 16.

FIG. 20 is a perspective view of a combination wafer including an integrated circuit wafer and HSWP wafer according to embodiments of the present technology.

FIG. 21 is a sectional view of a combination wafer including an integrated circuit wafer and HSWP wafer according to embodiments of the present technology.

FIG. 22 is a perspective view of a combination wafer including an integrated circuit wafer and HSWP wafer at a further stage of fabrication according to embodiments of the present technology.

FIG. 23 is a sectional view of a combination wafer including an integrated circuit wafer and HSWP wafer at a further stage of fabrication according to embodiments of the present technology.

FIG. 24 is a sectional view of a completed HSWP controller die according to embodiments of the present technology.

FIG. 25 is a sectional view of a completed HSWP memory die according to embodiments of the present technology.

FIG. 26 is a flowchart of the overall assembly process of a semiconductor device including an HWSP controller die and/or an HSWP memory die according to embodiments of the present technology.

FIG. 27 is a top view of a panel of substrates on which the semiconductor devices of the present technology may be constructed.

FIG. 28 is a top view of a substrate used in the assembly of a semiconductor device according to an embodiment of the present technology.

FIG. 29 is a sectional view of a substrate used in the assembly of a semiconductor device according to an embodiment of the present technology.

FIG. 30 is a top view of a substrate and HSWP controller die according to an embodiment of the present technology.

FIG. 31 is a sectional view of a substrate and HSWP controller die according to an embodiment of the present technology.

FIG. 32 is a top view of a substrate, HSWP controller die and a stack of memory dies including an uppermost HSWP memory die according to an embodiment of the present technology.

FIG. 33 is a sectional view of a substrate, HSWP controller die and a stack of memory dies including an uppermost HSWP memory die according to an embodiment of the present technology.

FIG. 34 is a sectional view of a completed HSWP semiconductor device according to embodiments of the present technology.

FIG. 35 is a perspective view of a completed HSWP semiconductor device according to embodiments of the present technology.

FIG. 36 is a perspective view of a completed HSWP semiconductor device according to a first alternative embodiment of the present technology.

FIG. 37 is a perspective view of a completed HSWP semiconductor device according to a second alternative of the present technology.

### DETAILED DESCRIPTION

The present technology will now be described with reference to the drawings, which in embodiments, relate to a semiconductor device including a controller semiconductor die and a stack of one or more semiconductor memory dies. In embodiments, the controller semiconductor die may have an integrated heat sink window plate, or HSWP, formed on top of the die. In further embodiments, an uppermost semiconductor memory die in the stack of memory dies may include an integrated HSWP.

The HSWP may be formed on the semiconductor controller die and/or the semiconductor memory die at the wafer level. The integrated circuit wafer (either controller or memory) is formed and thinned. In parallel, the HSWP wafer is formed including thin film deposition of various layers of the HSWP. The HSWP wafer may be mounted on the integrated circuit wafer, and joined wafers may then be diced into individual semiconductor devices with integrated HSWP.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

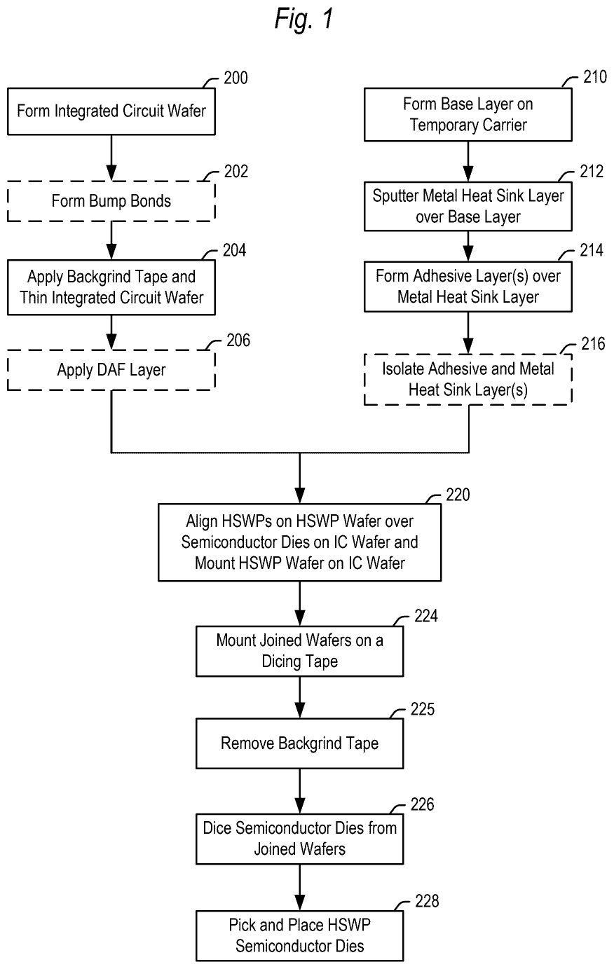

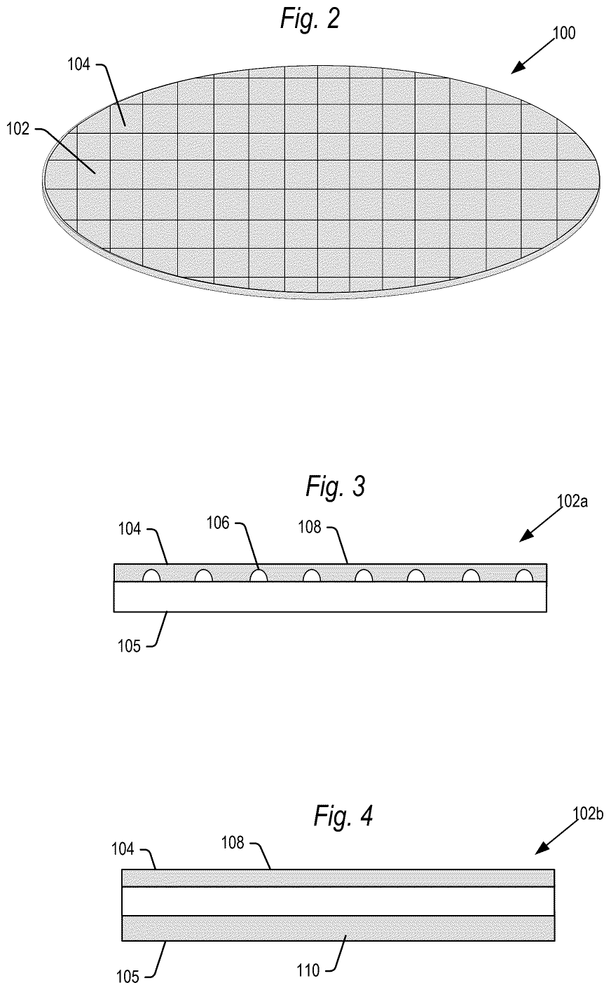

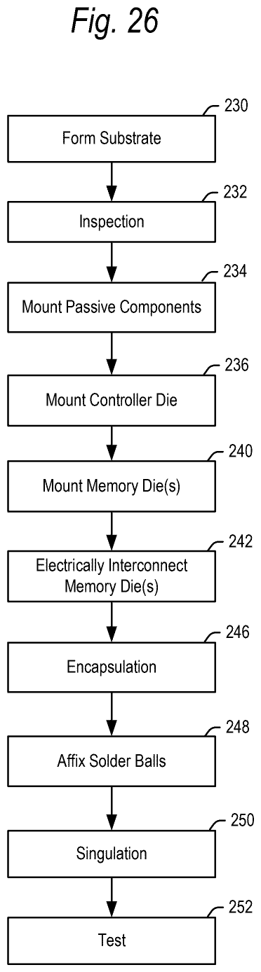

An embodiment of the present invention will now be explained with reference to the flowcharts of FIGS. 1 and 26 and the top, edge and perspective views of FIGS. 2 through 25 and 27 through 37. In steps 200-206, an integrated circuit wafer 100 (FIG. 2) is formed. As explained in greater below, the heat sink window plate (HSWP) of the present technology may be used on a semiconductor controller die and/or a semiconductor memory die. Steps 200-206 relate to the fabrication of both a wafer of controller dies or a wafer of memory dies. Where the fabrication steps differ for the controller and memory dies, those differences are noted.

The formation of integrated circuit wafer 100 is largely beyond the scope of the present technology, but in general, in step 200, the integrated circuit wafer 100 is processed to include individual semiconductor dies 102 (FIG. 2) having integrated circuits formed in an active surface 104, as well as metallization layers, vias and surface bond pads for carrying signals to and from the integrated circuits. As noted, the present technology may be used on two different types of semiconductor dies. Semiconductor dies 102a shown in the sectional view of FIG. 3 may be a controller die such as an ASIC or specialized processor such as a graphics processing unit or artificial intelligence (AI) processing unit. Semiconductor die 102b shown in the sectional view of FIG. 4 may be a memory die, such as for example a 3D NAND flash memory or bit cost scalable (BiCS) flash memory die.

Where wafer 100 includes controller dies 102a, bump bonds 106 may be formed on the bond pads in step 202 enabling the controller dies to be physically and electrically coupled to a substrate in a flip-chip mounting scheme as explained below. Step 202 is shown in dashed lines, as it may be skipped where wafer 100 includes memory dies 102b.

In step 204, a backgrind tape 108 may be applied to the active surface 104 of the wafer 100. Thereafter, the wafer may be flipped over, and the wafer 100 may be thinned from its inactive surface 105 with the backgrind tape 108 resting against a chuck. The wafer 100 may be thinned from an initial thickness of 760 μm down to its final thickness in step 204. This thickness may vary depending on whether wafer 100 includes controller dies 102a or memory dies 102b.

Where wafer 100 includes memory dies 102b, a die attach film (DAF) layer 110 may be applied to the inactive surface 105 in step 206. Step 206 is shown in dashed lines as it may be skipped where wafer 100 includes controller dies 102a.

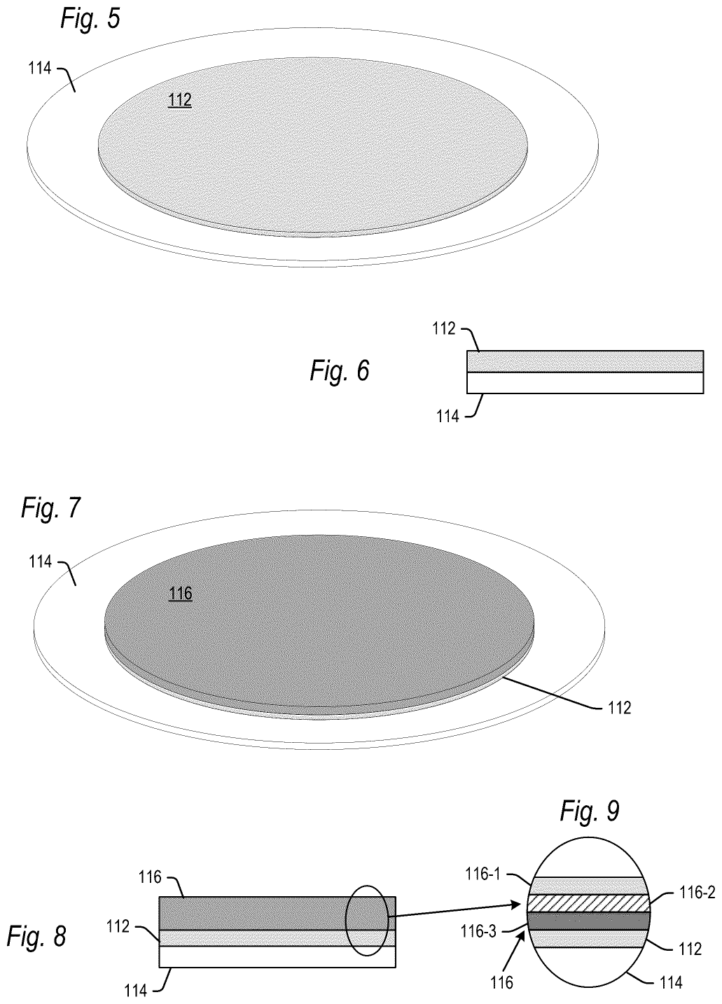

Before, during or in parallel with the formation of integrated circuit wafer 100, a heat sink window plate (HSWP) wafer may be fabricated in steps 210-216. In step 210, a base layer 112 may be formed on a temporary carrier 114 as shown in the perspective and sectional views of FIGS. 5 and 6. The base layer 112 may be formed of a polymer such as for example Polydimethylsiloxane (PDMS). Other materials are possible. The base layer 112 may be spin-coated onto the temporary carrier 114 or otherwise applied over the surface of the carrier 114. The base layer 112 may undergo a curing step to harden the base layer after it is applied.

In step 212, one or more thermally conductive heat sink layers 116 are applied over the base layer 112 as shown in the perspective, sectional and enlarged sectional views of FIGS. 7, 8 and 9, respectively. As seen in FIG. 9, in one example, the one or more heat sink layers may consist of three sublayers-116-1, 116-2 and 116-3, where the layers together are provided to optimize the heat transfer capability of the heat sink window plate as explained below. In one example, the first (top) sublayer 116-1 may be Chromium, the second sublayer 116-2 may be Nickel and the third sublayer 116-3 may be Copper.

In one example, the thickness of the first sublayer 116-1 may range from 1 to 5 microns (μm), the second sublayer 116-2 may range from 5-10 μm, and the third sublayer 116-3 may range from 90 to 130 μm. The overall thickness of the heat sink layers (Cu/Ni/Cr) may range from 100 μm to 150 μm. It is understood that these thicknesses are by way of example only and each sublayer may be thinner or thicker than this range in further embodiments. In one such further embodiment, the overall thickness of the heat sink layers (Cu/Ni/Cr) may range from 5 μm to 300 μm.

It is also understood that the number of sublayers may be more or less than three, and that the composition of each sublayer may be different than that set forth above. In one further embodiment, the heat sink layers 116 may be comprised entirely of Copper. Other materials may be included in heat sink layer 116 instead of, or in addition to, one or more of those materials set forth above, including for example Aluminum, Copper Alloys such as copper-tungsten (Cu—W) or copper-molybdenum (Cu—Mo), Aluminum Alloys such as aluminum-silicon (Al—Si), alloys of Copper and Aluminum, and graphite.

The one or more heat sink layers 116 may be applied one layer at a time onto the base layer 112 in successive processes. Each layer 116 may for example be applied by sputtering or other thin film deposition techniques. In embodiments, the heat sink layers 116 are applied directly onto the base layer 112. In further embodiments, a temporary adhesive layer (not shown) may be applied onto the base layer 112, and then the heat sink layers 116 applied onto the temporary adhesive layer. In such embodiments, the temporary adhesive layer may be dissolved later in the process as explained below. Where a temporary adhesive layer is used, the base layer 112 may be formed of a wide variety of materials including for example silicon.

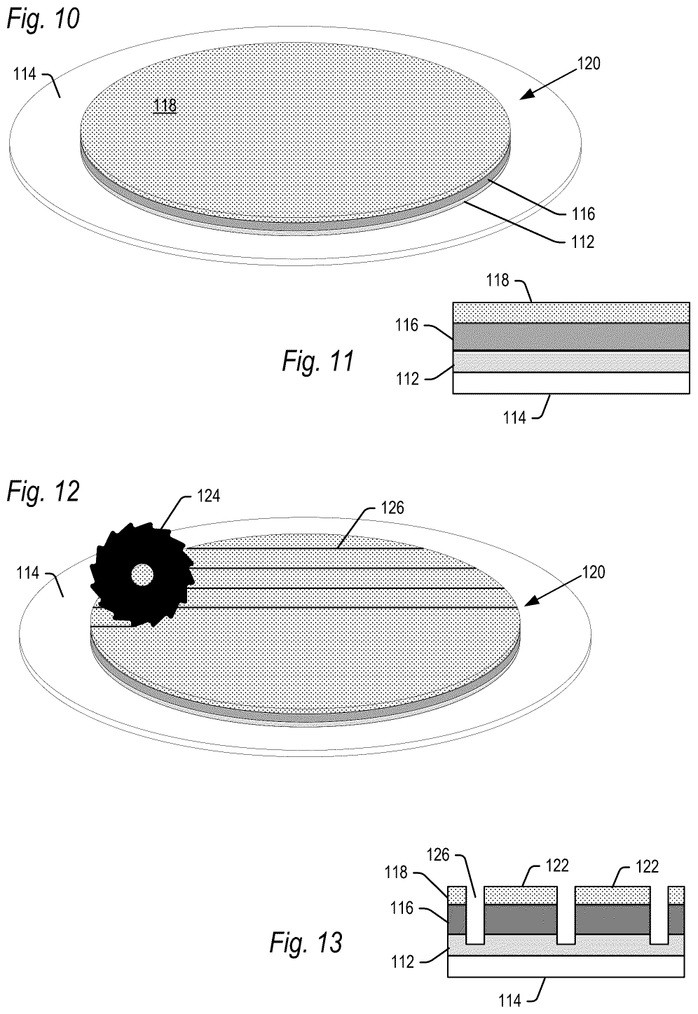

In step 214, an adhesive layer 118 may be applied over the heat sink layers 116 as shown in the perspective and sectional views of FIGS. 10 and 11, respectively. The addition of the adhesive layer 118 forms a completed HSWP wafer 120. The adhesive layer 118 is distinct from the temporary adhesive layer discussed above which, in embodiments, may be positioned between the base layer 112 and heat sink layers 116. The adhesive layer 118 can be made up of a curable epoxy or polymer material blended with fillers such as ceramic or metal oxide (i.e., silicon dioxide, aluminum oxide, aluminum nitride, etc.), and/or carbon nanotubes/nanofibers or graphene for higher heat dissipation. In embodiments, the adhesive layer 118 may have a thickness ranging from 5 μm to 100 μm, such as for example 10 μm to 30 μm. The adhesive layer may have other thicknesses in further embodiments.

In step 216, individual heat sink window plates (HSWPs) 122 may be isolated from each other on the HSWP wafer 120 as shown in the perspective and sectional views of FIGS. 12 and 13. In one embodiment, this may be done using a saw blade 124 that makes cuts 126 partially through the HSWP wafer 120 along horizontal and vertical lines. As seen in FIG. 13, the individual HSWPs 122 are formed by making a cut through the adhesive layer 118, through the heat sink layer 116 and partially into the base layer 112. It is understood that the partial depth cuts 126 may be accomplished by other techniques, including by a laser. As explained below, when the individual HSWPs 122 are removed from HSWP wafer 120, the individual HSWPs may comprise the adhesive layer 118 and the heat sink layer 116. These layers get separated from the base layer 112 and carrier 114, which may then be discarded.

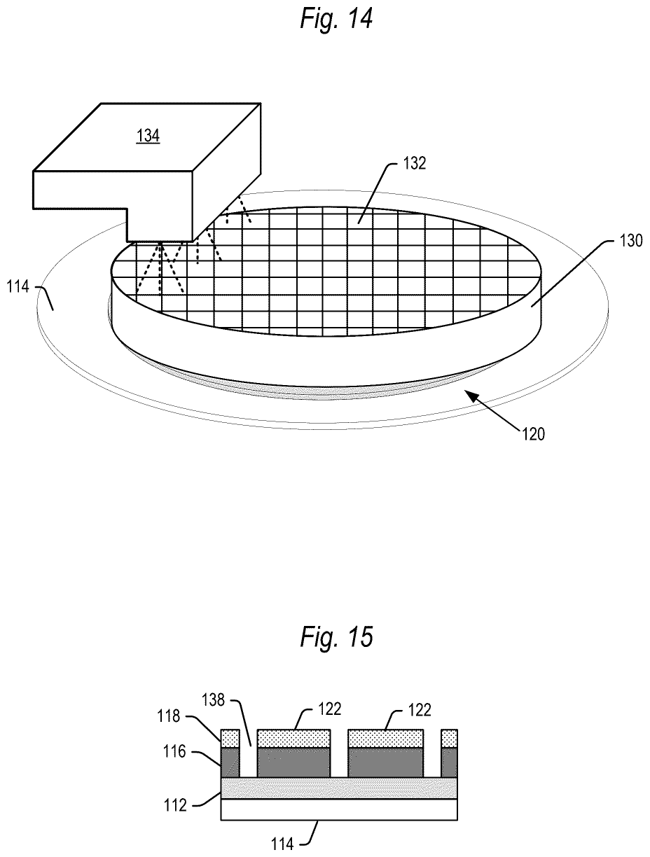

Step 216 is shown in dashed lines as this step may be omitted in further embodiments which use a shadow mask when forming the heat sink and adhesive layers. In particular, as shown in the perspective and sectional views of FIGS. 14 and 15, respectively, a shadow mask 130 may be used during the one or more heat sink layer depositions of step 212. The deposition device 134 sputters or otherwise deposits the respective layers of heat sink material 116 (e.g., Copper, Nickel and Chromium) on base layer 112 through the shadow mask 130. The shadow mask 130 has openings 132 defined so that the heat sink material 116 is only deposited where desired (in the pattern of individual HSWPs 122), leaving spaces 138 between the HSWPs 122. The adhesive layer 118 is similarly deposited through the shadow mask 130 to deposit material only on top of the heat sink material to complete the HSWPs 122 as shown in FIG. 15. In embodiments using the shadow mask 130, there is no need to isolate the HSWPs 122 using a saw blade and step 216 may be omitted.

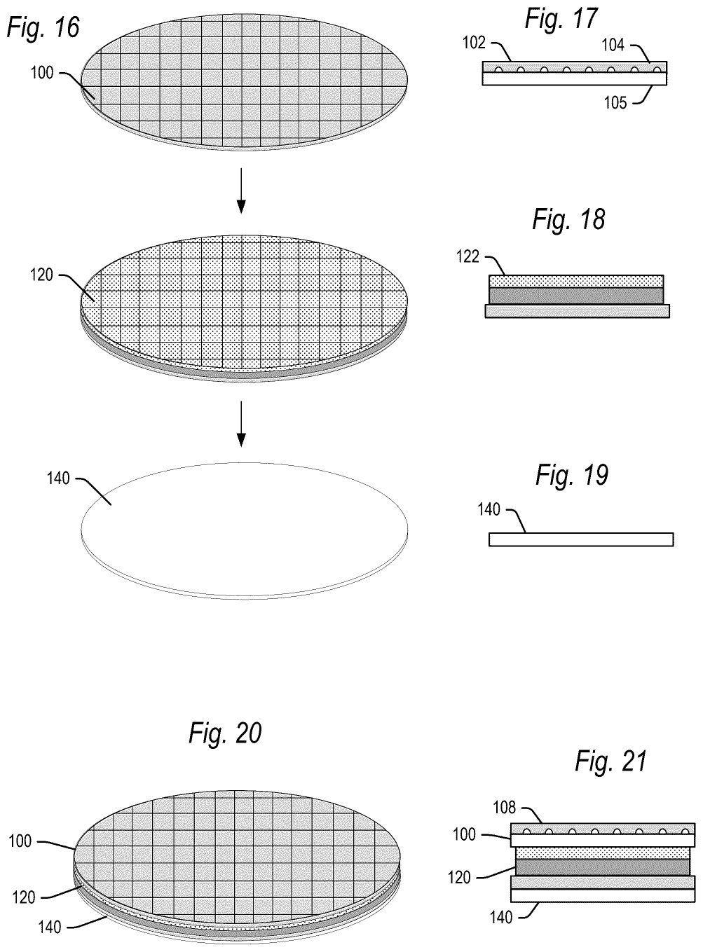

In step 220, the integrated circuit wafer 100 and the HSWP wafer 120 may be aligned and joined to each other as shown in the exploded perspective, perspective and sectional views of FIGS. 16-21. In particular, FIG. 16 shows an exploded perspective view of integrated circuit wafer 100 positioned for joining to the HSWP wafer 120. FIG. 17 is a sectional view of an individual semiconductor die 102 (a controller die 102a in this example). FIG. 18 is a sectional view of an individual HSWP 122. As seen, at this point in the process, the temporary carrier 114 has been removed from the HSWP wafer 120.

As indicated in the views of FIGS. 17 and 18, where the integrated circuit wafer 100 includes controller dies 102a, the wafer 100 is positioned with the active surface 104 of integrated circuit wafer 100 facing away from the HSWP wafer 120, and the inactive surface 105 facing the HSWP wafer 120. As explained below, where wafer 100 includes memory dies 102b, the opposite is true-the integrated circuit wafer 100 is positioned with the inactive surface 105 of integrated circuit wafer 100 facing away from the HSWP wafer 120, and the active surface 104 facing the HSWP wafer 120.

The individual HSWPs 122 are sized so as to match in number, shape and position to the individual semiconductor dies 102 on integrated circuit wafer 100. The HSWPs 122 may be slightly smaller than the semiconductor dies 102 on integrated circuit wafer 100, at least with respect to one of the length and width of the HSWPs 122 and dies 102. The respective wafers 100 and 120 are aligned to each other so that, when joined, the individual HSWPs 122 are aligned on top of the individual semiconductor dies 102.

The exploded perspective view of FIG. 16 and sectional view of FIG. 19 further shows a dicing tape 140 onto which the base layer 112 of the HSWP wafer 120 is mounted in step 224. As is known, the dicing tape may have an adhesive surface to hold individual dies in place after the wafers have been diced as explained below. The HSWP wafer 120 may be mounted to the dicing tape in step 224 before, after or at the same time the integrated circuit wafer 100 is mounted to the HSWP wafer 120 in step 220.

FIGS. 20 and 21 are perspective and sectional views of the finished, combined wafers including the dicing tape 140, the HSWP wafer 120 mounted on the dicing tape 140, and the integrated circuit wafer 100 mounted on the HSWP wafer 120. The adhesive layer 118 of the HSWP wafer 120 is used to securely and permanently affix the HSWP wafer 120 to the integrated circuit wafer 100.

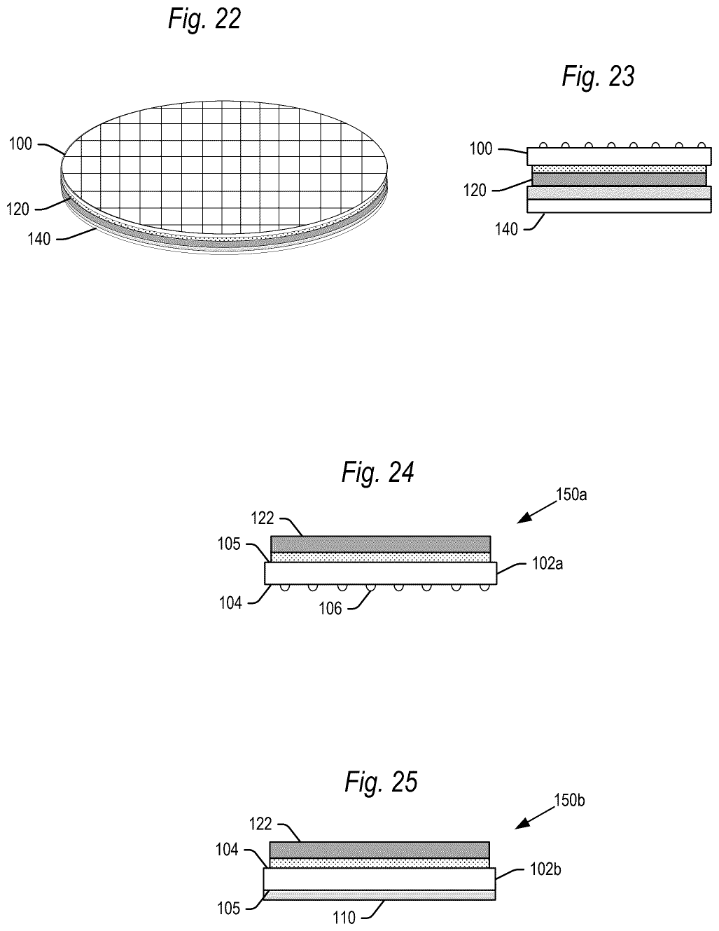

At this stage in the assembly, the integrated circuit wafer 100 still has the backgrind tape 108. The backgrind tape may be removed in step 225 as shown in the perspective and sectional views of FIGS. 22 and 23. In step 226, the individual combined semiconductor dies 102 and HSWPs 122 may be diced. Known dicing techniques may be used including saw blade, water jet and stealth laser dicing.

In step 228, the induvial combined semiconductor dies 102 and HSWPs 122 may be picked off of the dicing tape 140 by a pick and place robot. The adhesive forces between the base layer 112 and dicing tape 140 are greater than the adhesive forces between the base layer 112 and heat sink layer(s) 116. Thus, when the combined semiconductor dies 102 and HSWPs 122 are picked in step 228, the base layer 112 separates from the HSWPs 122 and remains on the dicing tape. The base layer may be heated or chemically treated in step 228 to reduce its adhesion to the heat sink layer(s) 116 to allow easier separation. As noted above, in some embodiments, an adhesive layer may be provided between the base layer 112 and heat sink layer(s) 116 (this adhesive layer is separate and distinct from adhesive layer 118). In such embodiments, this adhesive layer between the base layer 112 and heat sink layer(s) 116 may be heated or chemically treated in step 228 to allow removal of the HSWPs with base layer 112 and adhesive layer remaining on the dicing tape 140.

The finished individual combined semiconductor dies 102 and HSWPs 122 are referred to herein as HSWP dies 150. A completed HSWP controller die 150a is shown in FIG. 24. The HSWP controller die 150a includes the HSWP 122 on the inactive surface 105 of die 102a, and bump bonds 106 on the active surface 104 of the die 102a. A completed HSWP memory die 150b is shown in FIG. 25. As noted, the HSWP memory die 150b may be assembled from wafers 100 and 120 as described above. However, when assembling memory wafer 100 to HSWP wafer 120, the active surface 104 of wafer 100 is joined to the HSWP wafer 120. Thus, as shown in FIG. 25, the completed HSWP memory die 150b includes the HSWP 122 on the active surface 104 of die 102b, and the DAF layer 110 on the inactive surface 105 of the die 102b.

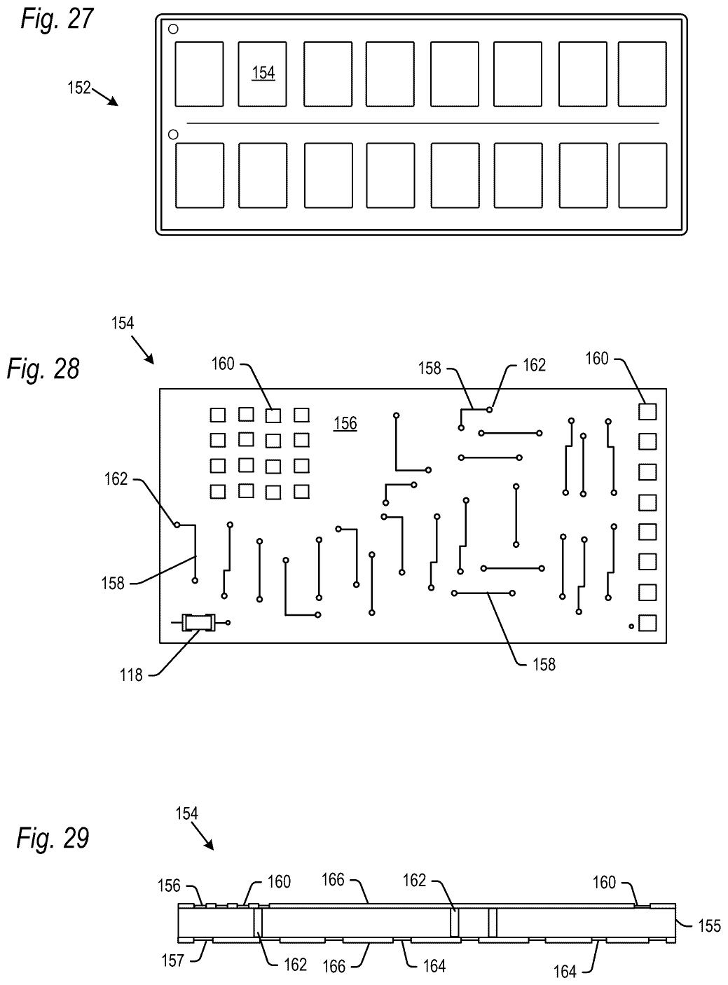

The assembly of HSWP controller dies 150a and/or HSWP memory dies 150b into a semiconductor package will now be described with reference to the flowchart of FIG. 26 and the top, edge and perspective views of FIGS. 27 through 37. As indicated in the top view of FIG. 27, the semiconductor packages may be formed on a substrate panel 152 including a number of substrates 154 for economies of scale. The particular number and arrangement of substrate 154 on panel 152 is shown by way of example only, and may vary in further embodiments.

The substrate 154 may be formed in step 230 as shown in the top and edge views of FIGS. 28 and 29, respectively. The substrate panel begins with a plurality of substrates 154 (one such substrate is shown in FIGS. 28 and 29). The substrate 154 may be a variety of different chip carrier mediums for transmitting signals between semiconductor dies on the substrate and a host device. Such chip carrier mediums may include a printed circuit board (PCB), a leadframe or a tape automated bonded (TAB) tape. Where substrate 154 is a PCB, the substrate may be formed of a core 155 having a top conductive layer 156 and a bottom conductive layer 157 as indicated in FIGS. 28 and 29. It is understood that the substrate may have more conductive layers, each separated by a dielectric core layer. The core 155 may be formed of various dielectric materials such as for example, polyimide laminates, epoxy resins including FR4 and FR5, bismaleimide triazine (BT), and the like. The conductive layers 156, 157 may be formed of copper or copper alloys, plated copper or plated copper alloys, Alloy 42 (42Fe/58Ni), copper plated steel, or other metals and materials known for use on substrate panels.

Conductance patterns are formed in one or both of the top and bottom conductive layers 156, 157. The conductance pattern(s) may include electrical traces 158 and contact pads 160 as shown for example in FIGS. 2 and 3. The traces 158 and contact pads 160 (only some of which are numbered in the figures) are by way of example, and the substrate 154 may include more traces and/or contact pads than is shown in the figures, and they may be in different locations than is shown in the figures. The substrate 154 may be drilled to define a number of vias 162 in the substrate 154. The vias 162 (only some of which are numbered in the figures) are by way of example, and the substrate 154 may include more vias 162 than are shown in the figures, and they may be in different locations than are shown in the figures.

The top conductance pattern 156 of the substrate 154 may be etched to include contact pads 160 for receiving solder balls and/or bond wires as explained below. The lower conductance pattern 157 of the substrate 154 may also be etched to include contact pads 164 for receiving solder balls as explained below. The conductance patterns on the top and/or bottom surfaces of the substrate 154 may be formed by a variety of known processes, including for example various photolithographic processes. A solder mask 166 may be applied over the conductance patterns in the top and bottom surfaces, leaving the various contact pads 160, 164 exposed.

The substrate 154 may next be inspected and tested in step 232 to check electrical operation, and for contamination, scratches and discoloration. Assuming the substrate 154 passes inspection, passive components 168 (FIG. 28) may next be affixed to the substrate in a step 240. The one or more passive components may include for example one or more capacitors, resistors and/or inductors, though other components are contemplated. The passive component 168 shown is by way of example only, and the number, type and position may vary in further embodiments.

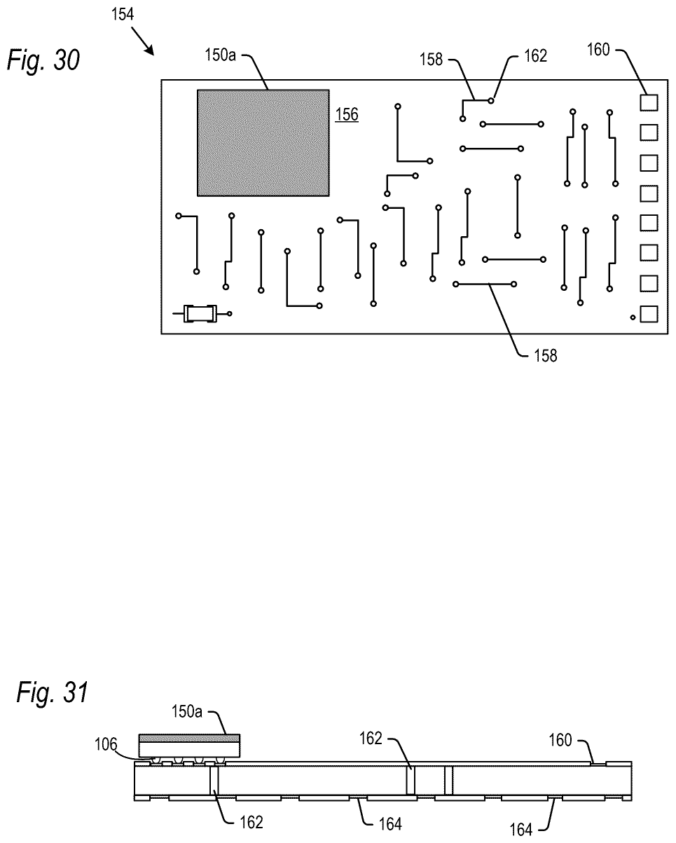

An HSWP controller die 150a may next be mounted on the substrate 154 in step 236 and as shown in the top and edge views of FIGS. 30 and 31, respectively. The HSWP controller die 150a may be mounted to the substrate 154 in a flip-chip configuration, using the bump bonds 106. The bump bonds 106 may be affixed to bond pads (not shown) on the HSWP controller die 150a, and onto contact pads 160 on the substrate 154. Once connected, the bump bonds 106 may be reflowed to physically and electrically couple the HSWP controller die 150a to the substrate 154.

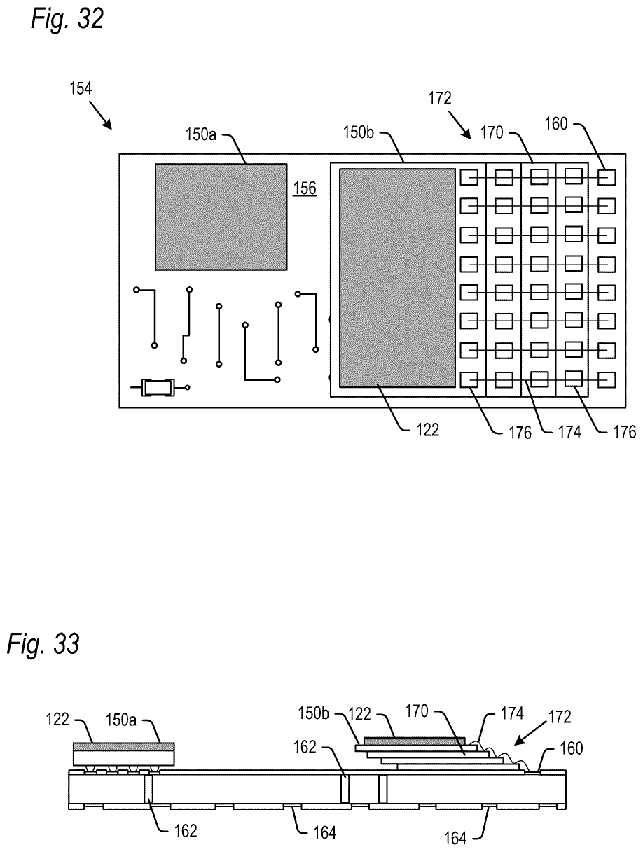

A number of memory dies 170 may next be mounted to the substrate 154 in a stack 172 in step 240 as shown in the top and edge views of FIGS. 32 and 33. In accordance with aspects of the present technology, an uppermost memory die in the stack may be an HSWP memory die 150b. The dies may be affixed to the substrate 154 and each other using a DAF layer, such as DAF layer 110 on HSWP memory die 150b. In step 242, the dies may be electrically coupled to the substrate and each other using bond wires 174 formed in a known wire bond process. In embodiments, the stack 172 may be offset stepped so that die bond pads 176 on each of the memory dies 170 are left exposed. Bond wires may be formed down the stack 172, electrically coupling corresponding bond pads 176 to each other and a contact pad 160 on the substrate 154. As noted above, the HSWP 122 may be slightly smaller than the semiconductor die 102b. Thus, bond pads 176 in the HSWP memory die 150b are left uncovered by the HSWP 122.

In the above description, the HSWP controller die 150a was mounted to the substrate before the memory die stack including HSWP memory die 150b was mounted and electrically coupled to the substrate. In further embodiments, the HSWP controller die 150a may be mounted to the substrate after the memory die stack including HSWP memory die 150b is mounted and electrically coupled to the substrate.

In a further embodiment, it is conceivable that the stack 172 of semiconductor dies be stacked directly on top of each other, without an offset. In such an embodiment, every die in the stack may be an HSWP memory die 150b. In such an embodiment, the HSWP 122 acts as a heat sink for carrying heat away from the memory dies, and also acts as a spacer, enabling wire bonds to be formed on the die bond pads 176 of each HSWP memory die 150b in the die stack 172.

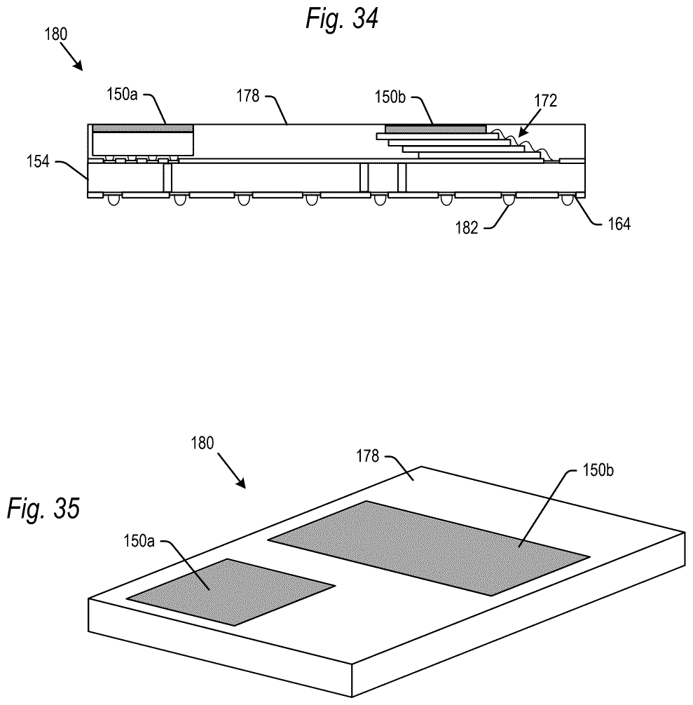

In step 246, the substrate 154 and semiconductor dies may be encapsulated in a mold compound 178 as shown in the edge and perspective views of FIGS. 34 and 35. The finished, encapsulated package is referred to herein as HSWP semiconductor device 180. In step 246, the panel 152 including the respective HSWP semiconductor devices 180 may be placed in a mold chase with the upper surfaces of the HSWPs 122 on both of the HSWP controller die 150a and HSWP memory die of each device 180 resting flush against a mold plate of the chase. Thus, when the encapsulation step 246 is completed, a surface of the HSWPs 122 on both of the HSWP controller die 150a and HSWP memory die in each device 180 remain exposed through a surface of the mold compound 178 as shown in FIG. 35.

In embodiments, the upper surface of the semiconductor device 180, including a surface of the mold compound 178 and the exposed surfaces of the HSWP 122 on the HSWP controller die 150a and HSWP memory die, is planar. As indicated above, when thinning a wafer 100 in step 204, the final thickness of the controller die 102a is coordinated with the final thickness of the memory die 102b, so that a height of the HSWP controller die 150a above a surface of the substrate 154 is equal to a height of the die stack 172 including HSWP memory die 150b. This allows the upper surface of the HSWP 122 on the controller die 150a to be coplanar with the upper surface of the HSWP 122 on the memory die 150b in the encapsulated package.

It is conceivable that the respective heights of the HSWP controller die 150a not be coordinated with the height of die stack 172 including HSWP memory die 150b, and that these heights not be coplanar in the HSWP semiconductor device 180. In such embodiments, the mold plate used in the encapsulation process may have two different elevations, configured so that an upper surface of the HSWP 122 in controller die 150a rests against the mold plate at a first elevation, and an upper surface of the HSWP 122 in memory die 150b rests against the mold plate at a second elevation different than the first.

In this way, both the HSWP controller die 150a and the HSWP memory die 150b have upper surfaces exposed in the different planes of the upper surface of the finished encapsulated device 180.

Mold compound 178 may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other encapsulants from other manufacturers are contemplated. Various encapsulation processes may be used, including for example transfer molding and FFT (Flow Free Thin) compression molding.

Solder balls 182 (FIG. 34) may be mounted to the contact pads 164 on a bottom surface of substrate 154 in step 248. The solder balls allow the HSWP semiconductor device 180 to be physically and electrically coupled to a host device such as a PCB.

The respective HSWP semiconductor devices 180 may be singulated from panel 152 in step 250 to form the finished HSWP semiconductor devices 180 shown in FIGS. 34 and 35. Each HSWP semiconductor device 180 may be singulated by any of a variety of cutting methods including sawing, water jet cutting, laser cutting, water guided laser cutting, dry media cutting, and diamond coating wire cutting. While straight line cuts will define generally rectangular or square shaped HSWP semiconductor devices 180, it is understood that devices 180 may have shapes other than rectangular and square in further embodiments of the present invention. Once cut into individual HSWP semiconductor devices 180s may be tested in a step 252 to ensure the devices are functioning properly.

Including the HSWPs 122 in the controller and memory dies 150a, 150b, and assembling the device 180 so that the HSWPs are exposed through a surface of the mold compound 178, provides an efficient and effective scheme for removing heat from the controller dies 150a and the memory dies 150b in the device 180. Moreover, assembling the HSWP 122 onto the controller and memory dies 150 at the wafer stage provides an efficient and effective method of assembling such memory dies 150.

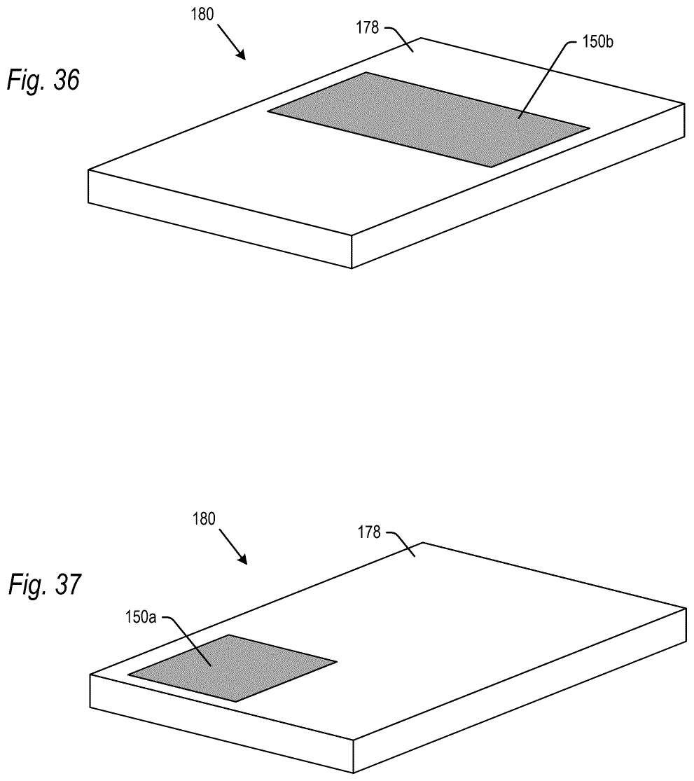

In embodiments described above, the HSWP semiconductor device 180 includes both an HSWP controller die 150a and an HSWP memory die 150b. However, in further embodiments, an HSWP semiconductor device 180 may include only one of an HSWP controller die 150a and an HSWP memory die 150b. For example, FIG. 36 is a perspective view of an HSWP semiconductor device 180 including an HSWP memory die 150b. This embodiment may include a conventional controller (i.e., one not having an HSWP mounted to its surface). As a further example, FIG. 37 is a perspective view of an HSWP semiconductor device 180 including an HSWP controller die 150a. This embodiment may include a conventional stack of memory dies (i.e., one not having an HSWP mounted to a surface of any of the memory dies).

In summary, in one example, the present technology relates to a semiconductor device, comprising: a substrate; a semiconductor controller die physically and electrically mounted to the substrate; one or more semiconductor memory dies physically and electrically mounted to each other and the substrate; one or more heat sink window plates (HSWPs) each having first and second surfaces, the first surface formed on one or more of a surface of the controller die and a surface of the uppermost memory die of the one or more memory dies; and an encapsulant for at least partially encapsulating the semiconductor device, wherein the second surface of the one or more HSWPs is exposed through the encapsulant.

In another example, the present technology relates to a combination semiconductor wafer, comprising: a first wafer comprising a plurality of integrated circuit dies; a second wafer comprising a plurality of heat sink window plates (HSWPs), each HSWP of the plurality of HSWPs comprising a heat sink and a thermally conductive adhesive; wherein the first wafer is aligned with the second wafer such that the plurality of integrated circuit dies align with the plurality of HSWPs; and wherein the aligned first and second wafers are coupled to each other by the thermally conductive adhesive on each HSWP.

In a further example, the present technology relates to a semiconductor device, comprising: a substrate; a controller die physically and electrically mounted to the substrate; one or more memory dies physically and electrically mounted to each other and the substrate; heat sink means, disposed on one or more of the controller die and an uppermost memory die of the one or more memory dies, for conducting heat away from the die on which the heat sink means is disposed; and an encapsulant for at least partially encapsulating the semiconductor device, wherein the heat sink means is exposed through the encapsulant.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a substrate;
a semiconductor controller die physically and electrically mounted to the substrate;
one or more semiconductor memory dies physically and electrically mounted to each other and the substrate;
one or more heat sink window plates (HSWPs) each having first and second surfaces, the first surface formed on one or more of a surface of the controller die and a surface of the uppermost memory die of the one or more memory dies; and
an encapsulant for at least partially encapsulating the semiconductor device, wherein the second surface of the one or more HSWPs is exposed through the encapsulant.

2. The semiconductor device of claim 1, wherein the controller die comprises a plurality of bump bonds for flip-chip mounting the controller die to the substrate, a first HSWP of the one or more HSWPs mounted on an inactive surface of the controller die.

3. The semiconductor device of claim 1, wherein the uppermost memory die comprises a die attach film layer for mounting the memory die to the substrate, a second HSWP of the one or more HSWPs mounted on an active surface of the memory die.

4. The semiconductor device of claim 1, wherein an HSWP of the one or more HSWPs is comprised of a plurality of sublayers.

5. The semiconductor device of claim 4, wherein a first sublayer of the HSWP is comprised of Copper.

6. The semiconductor device of claim 5, wherein a second sublayer of the HSWP is comprised of a thermally conductive adhesive.

7. The semiconductor device of claim 6, wherein a third sublayer of the HSWP is comprised of Nickel and a fourth sublayer of the HSWP is comprised of Chromium.

8. The semiconductor device of claim 1, wherein the encapsulant is applied to the semiconductor device after the one or more HSWPs are affixed to one of the controller die and the memory die.

9. The semiconductor device of claim 1, wherein an HSWP of the one or more HSWPs is affixed to the controller die, and wherein the HSWP and controller die are diced from a combined wafer including a plurality of HSWPs and a plurality of controller dies.

10. The semiconductor device of claim 1, wherein an HSWP of the one or more HSWPs is affixed to the memory die, and wherein the HSWP and memory die are diced from a combined wafer including a plurality of HSWPs and a plurality of memory dies.

11. The semiconductor device of claim 1, wherein both of the controller die and the one or more memory dies have an HSWP of the one or more HSWPs affixed to its surface.

12. The semiconductor device of claim 11, wherein the exposed second surface of the HSWP on the controller die is coplanar with the exposed second surface of the HSWP on the memory die.

13. A combination semiconductor wafer, comprising:
a first wafer comprising a plurality of integrated circuit dies;
a second wafer comprising a plurality of heat sink window plates (HSWPs),
each HSWP of the plurality of HSWPs comprising a heat sink and a
thermally conductive adhesive;
wherein the first wafer is aligned with the second wafer such that the plurality of integrated circuit dies align with the plurality of HSWPs; and
wherein the aligned first and second wafers are coupled to each other by the thermally conductive adhesive on each HSWP.

14. The combination semiconductor wafer of claim 13, wherein the integrated circuit dies of the first wafer comprise controller dies having an active surface and an inactive surface opposite the active surface.

15. The combination semiconductor wafer of claim 14, wherein adhesive layers of the HSWPs on the second wafer are affixed to the inactive surfaces of the controller dies.

16. The combination semiconductor wafer of claim 13, wherein the integrated circuit dies of the first wafer comprise memory dies having an active surface and an inactive surface opposite the active surface.

17. The combination semiconductor wafer of claim 16, wherein adhesive layers of the HSWPs on the second wafer are affixed to the active surfaces of the memory dies.

18. The combination semiconductor wafer of claim 13, wherein the HSWPs in the second wafer are designed to match in number and position to the integrated circuit dies on the first wafer, and wherein divisions between HSWPs in the second wafer are defined by a saw street or a shadow mask.

19. The combination semiconductor wafer of claim 13, further comprising a base layer on which the heat sink is formed on the second wafer.

20. A semiconductor device, comprising:
a substrate;
a controller die physically and electrically mounted to the substrate;
one or more memory dies physically and electrically mounted to each other and the substrate;
heat sink means, disposed on one or more of the controller die and an uppermost memory die of the one or more memory dies, for conducting heat away from the die on which the heat sink means is disposed; and
an encapsulant for at least partially encapsulating the semiconductor device, wherein the heat sink means is exposed through the encapsulant.
